(19) United States
(12) Patent Application Publication
(10) Pub. No.: US 2017/0194162 A1
(43) Pub. Date: Jul. 6, 2017

(54) SEMICONDUCTOR MANUFACTURING EQUIPMENT AND METHOD FOR TREATING WAFER

(71) Applicant: TAIWAN SEMICONDUCTOR MANUFACTURING CO., LTD., Hsinchu (TW)

(72) Inventors: Hsin-Chih LIU, Hsinchu County (TW); Chia-Hung HUANG, Hsinchu City (TW); Jen-Chung CHEN, Hsinchu City (TW); Tung-Ching TSENG, Taipei City (TW)

(21) Appl. No.: 14/988,674

(22) Filed: Jan. 5, 2016

(51) Int. Cl. H01L 21/324; H01L 21/67

(52) U.S. Cl. CPC H01L 21/324; H01L 21/67115

(57) ABSTRACT

A semiconductor manufacturing equipment includes a processing chamber, at least one reflector and at least one electromagnetic wave emitting device. The reflector is present in the processing chamber. The electromagnetic wave emitting device is present between the reflector and a wafer in the processing chamber. The electromagnetic wave emitting device is configured to emit a spectrum of electromagnetic wave to the wafer. The reflector has a relative reflectance to Al₂O₃ with respect to the spectrum of electromagnetic wave, and the relative reflectance of the reflector is in a range from about 70% to about 120%.

### BACKGROUND

The present disclosure generally relates to semiconductor manufacturing equipments.

Throughout a semiconductor manufacturing process, a number of procedures are carried out to treat the wafer. Among these procedures, the application of light treatment is involved. In general, the light treatment includes the applications of flash annealing, ultraviolet (UV) curing and heating by infrared (IR), etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a semiconductor manufacturing equipment in accordance with some embodiments of the present disclosure.

FIG. 2 is a partially magnified view of the reflector of FIG. 1.

FIG. 3 is a schematic view of a semiconductor manufacturing equipment in accordance with some other embodiments of the present disclosure.

FIG. 4 is a schematic view of a semiconductor manufacturing equipment in accordance with yet some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, operations, operations, elements, and/or components, but do not preclude the presence or addition of one or more other features, regions, integers, operations, operations, elements, components, and/or groups thereof.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

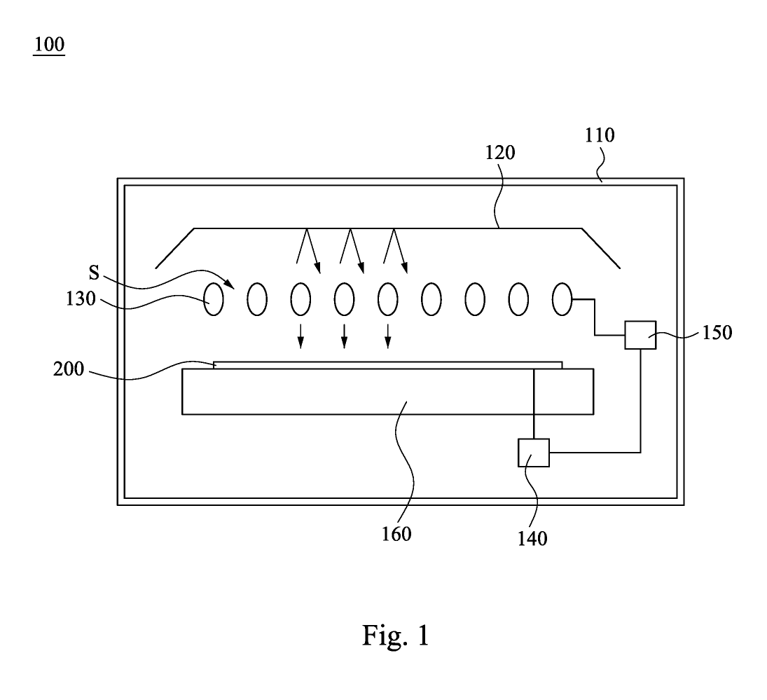

Reference is made to FIG. 1. FIG. 1 is a schematic view of a semiconductor manufacturing equipment 100 in accordance with some embodiments of the present disclosure. As shown in FIG. 1, the semiconductor manufacturing equipment 100 includes a processing chamber 110, at least one reflector 120 and at least one electromagnetic wave emitting device 130. The reflector 120 is present in the processing chamber 110. The electromagnetic wave emitting device 130 is present between the reflector 120 and a wafer 200 in the processing chamber 110. The electromagnetic wave emitting device 130 is configured to emit a spectrum of electromagnetic wave to the wafer 200. The reflector 120 has a reflectance with respect to the spectrum of electromagnetic wave, and the reflectance of the reflector 120 is in a range from about 90.5% to about 99.9%.

In practical applications, during the operation of the semiconductor manufacturing equipment 100, the electromagnetic wave emitting device 130 emits a spectrum of electromagnetic wave and at least a part of the spectrum of electromagnetic wave propagates to the wafer 200 and arrives at the wafer 200 in a period of time. In the same period of time, however, another part of the spectrum of electromagnetic wave emitted by the electromagnetic wave emitting device 130 propagates in a direction away from the wafer 200. As shown in FIG. 1, the reflector 120 is present at a side of the electromagnetic wave emitting device 130 opposite to the wafer 200. When the spectrum of electromagnetic wave propagating away from the wafer 200 arrives at the reflector 120, the reflector 120 reflects the spectrum of electromagnetic wave initially propagating away from the wafer 200 back to the wafer 200. In this way, a majority of the spectrum of electromagnetic wave emitted by the electromagnetic wave emitting device 130 is directed to the wafer 200. To be more specific, the percentage of the spectrum of electromagnetic wave being reflected by the reflector 120 depends on the reflectance of the reflector 120, which ranges from about 90.5% to about 99.9% as mentioned above. For example, if about 90% of the spectrum of electromagnetic wave is reflected by the reflector 120, this means about 10% of the spectrum of electromagnetic wave will be absorbed by the reflector 120.

As compared to the material of aluminum oxide Al₂O₃, the reflector 120 has a relative reflectance to Al₂O₃ with respect to the spectrum of electromagnetic wave. In some embodiments, the relative reflectance of the reflector 120 is in a range from about 70% to about 120% as compared to Al₂O₃. Since the relative reflectance of the reflector 120 can be greater than about 70% as compared to Al₂O₃, the reflector 120 can reflect a higher percentage of the spectrum of electromagnetic wave initially propagating away from the wafer 200 back to the wafer 200. In other words, when the spectrum of electromagnetic wave emitted by the electromagnetic wave emitting device 130 initially propagating away from the wafer 200 reaches the reflector 120, a lower percentage of the spectrum of electromagnetic wave initially propagating away from the wafer 200 will be absorbed by the reflector 120.

Since the reflector 120 reflects the spectrum of electromagnetic wave initially propagating away from the wafer 200 back to the wafer 200, the percentage of the spectrum of electromagnetic wave emitted by the electromagnetic wave emitting device 130 which is directed to the wafer 200 is increased by the reflector 120. As a result, for the same amount of spectrum of electromagnetic wave to be directed to the wafer 200, less power is required to generate the electromagnetic wave emitting device 130 to emit the spectrum of electromagnetic wave. Therefore, the operating cost of the semiconductor manufacturing equipment 100 is reduced, while the efficiency of the semiconductor manufacturing equipment 100 is increased. In practical applications, in some embodiments, the electromagnetic wave emitting device 130 has at least an electrode disposed inside. With less power supplied to the electromagnetic wave emitting device 130 for emitting the spectrum of electromagnetic wave, the degradation rate of the electrode disposed inside the electromagnetic wave emitting device 130 is correspondingly slowed down. Hence, the working life of the electromagnetic wave emitting device 130 is also correspondingly increased.

Furthermore, in order to achieve an even reflection of the spectrum of electromagnetic wave emitted by the electromagnetic wave emitting device 130, the reflector 120 has a diffuse reflectance with respect to the spectrum of electromagnetic wave. In some embodiments, the diffuse reflectance of the reflector 120 is in a range from about 90.5% to about 99.9%.

As compared to the material of Al₂O₃, the reflector 120 has a relative diffuse reflectance to Al₂O₃ with respect to the spectrum of electromagnetic wave. In some embodiments, the relative diffuse reflectance of the reflector 120 is in a range from about 90% to about 110% as compared to Al₂O₃. Since the relative diffuse reflectance of the reflector 120 can be greater than about 90% as compared to Al₂O₃, the reflector 120 can achieve a more even reflection when reflecting the spectrum of electromagnetic wave initially propagating away from the wafer 200 back to the wafer 200. In other words, when the spectrum of electromagnetic wave emitted by the electromagnetic wave emitting device 130 initially propagating away from the wafer 200 reaches the reflector 120, the spectrum of electromagnetic wave initially propagating away from the wafer 200 will be reflected by the reflector 120 in a more even manner.

In order to maintain the intensity of the spectrum of electromagnetic wave emitted by the electromagnetic wave emitting device 130, the semiconductor manufacturing equipment 100 further includes a sensor 140 and a power control 150. The sensor 140 is configured for detecting an intensity of the spectrum of electromagnetic wave arriving at the wafer 200. On the other hand, the power control 150 is electrically connected to the electromagnetic wave emitting device 130. The power control 150 is configured for supplying a power to the electromagnetic wave emitting device 130 according to the intensity of the spectrum of electromagnetic wave detected by the sensor 140. For example, if the electrode disposed inside the electromagnetic wave emitting device 130 is degraded after a time period of utilization and the intensity of the spectrum of electromagnetic wave emitted by the electromagnetic wave emitting device 130 is reduced, the sensor 140 will detect the reduced intensity of the spectrum of electromagnetic wave arriving at the wafer 200. Consequently, the power control 150 will supply more power to the electromagnetic wave emitting device 130 according to the reduced intensity of the spectrum of electromagnetic wave detected by the sensor 140, so as to maintain the intensity of the spectrum of electromagnetic wave emitted by the electromagnetic wave emitting device 130.

Furthermore, the semiconductor manufacturing equipment 100 further includes a heater 160. The heater 160 is present in the processing chamber 110 and is configured to allow the wafer 200 to be disposed thereon. In other words, during the operation of the semiconductor manufacturing equipment 100, the wafer 200 is disposed on the heater 160. The heater 160 works to increase the temperature of the wafer 200 according to actual situations.

In some embodiments, as shown in FIG. 1, the number of the electromagnetic wave emitting device 130 is plural and there exists a space S between the adjacent electromagnetic wave emitting devices 130. In this way, when the spectrum of electromagnetic wave initially propagating away from the wafer 200 reaches the reflector 120, the spectrum of electromagnetic wave initially propagating away from the wafer 200 will be reflected by the reflector 120 and the spectrum of electromagnetic wave reflected by the reflector 120 will pass the spaces S and propagate towards the wafer 200.

In some practical applications, the light treatment to the wafer 200 performed by the semiconductor manufacturing equipment 100 can be flash annealing. In flash annealing, light energy is applied on the surface of the wafer 200 in a period of time, for instance, between some hundred microseconds and some milliseconds. In this way, the surface of the wafer 200 is thermally treated and the quality of the wafer 200 is correspondingly improved.

In some embodiments, the electromagnetic wave emitting device 130 includes at least one visible light source. The visible light source is configured to emit a visible light. The wavelength of the visible light falls approximately between about 200 nm and about 900 nm approximately. During the operation of the semiconductor manufacturing equipment 100 for flash annealing, the visible light source of the electromagnetic wave emitting device 130 emits a visible light to the wafer 200 in a period of time, for instance, between some hundred microseconds and some milliseconds. In the same period of time, however, another part of the visible light emitted by the visible light source of the electromagnetic wave emitting device 130 propagates in a direction away from the wafer 200. When the visible light propagating away from the wafer 200 reaches the reflector 120, the reflector 120 reflects the visible light initially propagating away from the wafer 200 back to the wafer 200. In some embodiments, the range of the wavelength of the electromagnetic waves that the reflector 120 is capable to reflect is wide enough to include the wavelength of the visible light. In this way, a majority of the visible light emitted by the visible light source of the electromagnetic wave emitting device 120 is directed to the wafer 200.

Furthermore, as mentioned above, since the relative reflectance of the reflector 120 can be greater than about 70% as compared to Al₂O₃, the reflector 120 can reflect a higher percentage of the visible light initially propagating away from the wafer 200 back to the wafer 200. In other words, when the visible light emitted by the visible light source of the electromagnetic wave emitting device 130 initially propagating away from the wafer 200 reaches the reflector 120, a lower percentage of the visible light initially propagating away from the wafer 200 will be absorbed by the reflector 120. In some embodiments, for example, the reflector 120 can reflect the visible light initially propagating away from the wafer 200 back to the wafer 200 by over about 95%. This means the reflector 120 absorbs less than about 5% of the visible light initially propagating away from the wafer 200 when the visible light initially propagating away from the wafer 200 reaches the reflector 120.

In some practical applications, the light treatment to the wafer 200 performed by the semiconductor manufacturing equipment 100 can be ultraviolet (UV) curing. UV curing is a speed curing process in which ultraviolet is used to create a photochemical reaction that instantly cures inks, adhesives and coatings. UV curing is adaptable to printing, coating, decorating, stereo-lithography and assembling of a variety of products and materials owing to some of its attributes. UV curing is a low temperature process, a high speed process, and a solventless process. In UV curing, cure is by polymerization rather than by evaporation.

In some embodiments, the electromagnetic wave emitting device 130 includes at least one ultraviolet source. The ultraviolet source is configured to emit an ultraviolet light. The wavelength of the ultraviolet light approximately falls between about 100 nm and about 400 nm. During the operation of the semiconductor manufacturing equipment 100 for UV curing, the ultraviolet source of the electromagnetic wave emitting device 130 emits an ultraviolet light to the wafer 200 in a period of time. In the same period of time, however, another part of the ultraviolet light emitted by the ultraviolet source of the electromagnetic wave emitting device 130 propagates in a direction away from the wafer 200. When the ultraviolet light propagating away from the wafer 200 reaches the reflector 120, the reflector 120 reflects the ultraviolet light initially propagating away from the wafer 200 back to the wafer 200. In some embodiments, the range of the wavelength of the electromagnetic waves that the reflector 120 is capable to reflect is wide enough to include the wavelength of the ultraviolet light. In this way, a majority of the ultraviolet emitted by the ultraviolet light source of the electromagnetic wave emitting device 120 is directed to the wafer 200.

Furthermore, as mentioned above, since the relative reflectance of the reflector 120 can be greater than about 70% as compared to Al₂O₃, the reflector 120 can reflect a higher percentage of the ultraviolet light initially propagating away from the wafer 200 back to the wafer 200. In other words, when the ultraviolet light emitted by the ultraviolet source of the electromagnetic wave emitting device 130 initially propagating away from the wafer 200 reaches the reflector 120, a lower percentage of the ultraviolet light initially propagating away from the wafer 200 will be absorbed by the reflector 120. In some embodiments, for example, the reflector 120 can reflect the ultraviolet light initially propagating away from the wafer 200 back to the wafer 200 by over about 95%. This means the reflector 120 absorbs less than about 5% of the ultraviolet light initially propagating away from the wafer 200 when the ultraviolet initially propagating away from the wafer 200 reaches the reflector 120.

In some practical applications, infrared (IR) light is utilized in the light treatment. In some embodiments, the electromagnetic wave emitting device 130 includes at least one infrared source. The infrared source is configured to emit an infrared light. The wavelength of the infrared light falls approximately between about 700 nm and about 1 mm. During the operation of the semiconductor manufacturing equipment 100 for the application of infrared light, the infrared source of the electromagnetic wave emitting device 130 emits an infrared light to the wafer 200 in a period of time. In the same period of time, however, another part of the infrared light emitted by the infrared source of the electromagnetic wave emitting device 130 propagates in a direction away from the wafer 200. When the infrared light propagating away from the wafer 200 reaches the reflector 120, the reflector 120 reflects the infrared light initially propagating away from the wafer 200 back to the wafer 200. In some embodiments, the range of the wavelength of the electromagnetic waves that the reflector 120 is capable to reflect is wide enough to include the wavelength of the infrared light. In this way, a majority of the infrared light emitted by the infrared source of the electromagnetic wave emitting device 120 is directed to the wafer 200.

Furthermore, as mentioned above, since relative reflectance of the reflector 120 can be greater than about 70% as compared to Al₂O₃, the reflector 120 can reflect a higher percentage of the infrared light initially propagating away from the wafer 200 back to the wafer 200. In other words, when the infrared light emitted by the infrared source of the electromagnetic wave emitting device 130 initially propagating away from the wafer 200 reaches the reflector 120, a lower percentage of the infrared light initially propagating away from the wafer 200 will be absorbed by the reflector 120. In some embodiments, for example, the reflector 120 can reflect the infrared light initially propagating away from the wafer 200 back to the wafer 200 by over about 95%. This means the reflector 120 absorbs less than about 5% of the infrared light initially propagating away from the wafer 200 when the infrared initially propagating away from the wafer 200 reaches the reflector 120.

In some embodiments, the reflector 120 is made of a material including silver. In practical applications, the silver can be coated as a layer over the reflector 120. In other words, the reflector 120 has a surface facing the electromagnetic wave emitting device 130, and the said surface of the reflector 120 includes silver.

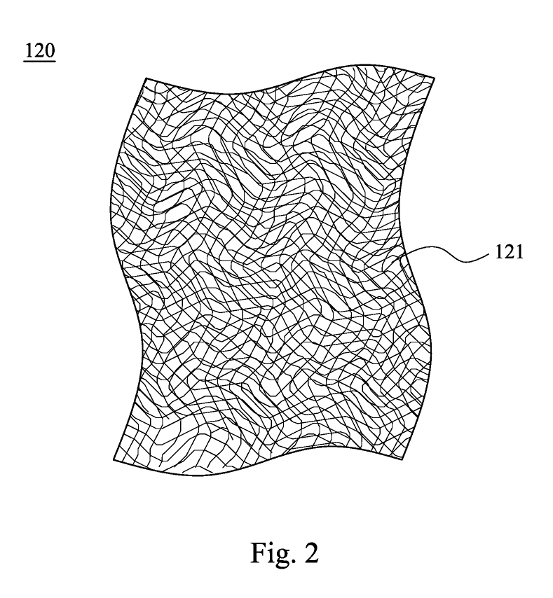

Reference is made to FIG. 2. FIG. 2 is a partially magnified view of the reflector 120 of FIG. 1. As shown in FIG. 2, in order to increase the reflectance of the reflector 120, the reflector 120 includes a plurality of fibrils 121 in a microscopic scale. The microscopic scale is the scale of objects and events smaller than those that can be seen by the naked eye but large enough to be seen under a microscope. The fibrils 121 are configured to reflect and refract the spectrum of electromagnetic wave such that the reflectance of the reflector 120 is increased. In other words, the reflector 120 has a surface facing the electromagnetic wave emitting device 130, and the fibrils 121 are present on the said surface thereof. Practically speaking, the reflector 120 is made of a material including polytetrafluoroethene (PTFE).

The reflector 120 with the fibrils 121 may have a substantially lambertian surface facing the electromagnetic wave emitting device 130 and/or the wafer 200. In other words, the surface of the reflector 120 facing the electromagnetic wave emitting device 130 and/or the wafer 200 is substantially lambertian. A luminance of the lambertian surface of the reflector 120 facing the electromagnetic wave emitting device 130 and/or the wafer 200 is substantially isotropic, which means that a brightness of the said surface is substantially the same regardless of an observer's angle of view from about 0° to about 180°.

In addition, in some embodiments, the reflector 120 can be made of aluminum alloys such as 5052 and 6061, such that the relative reflectance of the reflector 120 is in a range from about 70% to about 120% as compared to Al₂O₃.

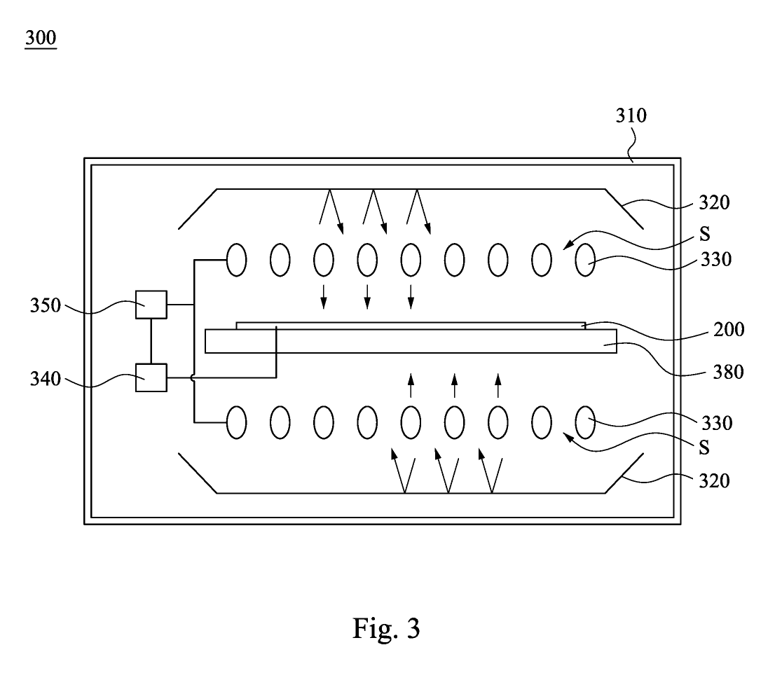

Reference is made to FIG. 3. FIG. 3 is a schematic view of a semiconductor manufacturing equipment 300 in accordance with some other embodiments of the present disclosure. In some embodiments, the semiconductor manufacturing equipment 300 further includes a wafer support 380. The wafer support 380 is configured to support the wafer 200. Meanwhile, a plurality of the electromagnetic wave emitting devices 330 is present at opposite sides of the wafer 200. As shown in FIG. 3, the semiconductor manufacturing equipment 300 includes a processing chamber 310. The electromagnetic wave emitting devices 330 are disposed in the processing chamber 310. The wafer 200 is located between the electromagnetic wave emitting devices 330.

In practical applications, the wafer support 380 is transparent to the spectrum of electromagnetic wave. In other words, when the electromagnetic wave emitting devices 330 located at the side of the wafer support 380 away from the wafer 200 emit a spectrum of electromagnetic wave towards the wafer 200, the spectrum of electromagnetic wave will penetrate through the wafer support 380 and reach the wafer 200.

In addition, as shown in FIG. 3, a plurality of the reflectors 320 is present at opposite sides of the wafer 200. Moreover, the electromagnetic wave emitting devices 330 are located between the reflectors 320.

In some embodiments, during the process of light treatment by the semiconductor manufacturing equipment 300, the electromagnetic wave emitting devices 330 present at the opposite sides of the wafer 200 emit a spectrum of electromagnetic wave and at least a part of the spectrum of electromagnetic wave propagates to the opposite sides of the wafer 200 in a period of time. In the same period of time, however, another part of the spectrum of electromagnetic wave emitted by the electromagnetic wave emitting devices 330 propagates in a direction away from the wafer 200. When the spectrum of electromagnetic wave propagating away from the wafer 200 reaches the reflectors 320, the reflectors 320 reflect the spectrum of electromagnetic wave initially propagating away from the wafer 200 back to the wafer 200. In this way, a majority of the spectrum of electromagnetic wave emitted by the electromagnetic wave emitting device 330 present at the opposite sides of the wafer 200 is directed to the opposite sides of the wafer 200.

Similarly, in order to maintain the intensity of the spectrum of electromagnetic wave emitted by the electromagnetic wave emitting devices 330, the semiconductor manufacturing equipment 300 further includes a sensor 340 and a power control 350. For example, if the electrode disposed inside each of the electromagnetic wave emitting devices 330 is degraded after a time period of utilization and the intensity of the spectrum of electromagnetic wave emitted by the electromagnetic wave emitting devices 330 is reduced, the sensor 340 will detect the reduced intensity of the spectrum of electromagnetic wave arriving at the wafer 200. Consequently, the power control 350 will supply more power to the electromagnetic wave emitting devices 330 according to the reduced intensity of the spectrum of electromagnetic wave detected by the sensor 340, so as to maintain the intensity of the spectrum of electromagnetic wave emitted by the electromagnetic wave emitting devices 330.

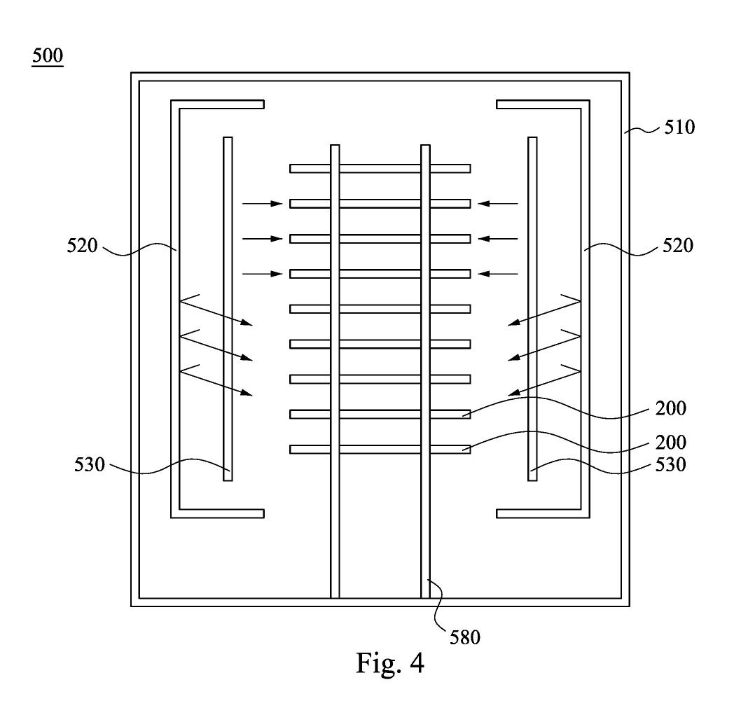

Reference is made to FIG. 4. FIG. 4 is a schematic view of a semiconductor manufacturing equipment 500 in accordance with yet some other embodiments of the present disclosure. In some embodiments, the semiconductor manufacturing equipment 500 includes a wafer support 580. The wafer support 580 is configured to support the wafer 200. As shown in FIG. 4, the wafer support 580 supports a plurality of wafers 200 such that the wafers 200 are stacked as a column in the processing chamber 510. Furthermore, the wafer support 580, and thus the column of the wafers 200, is surrounded by the electromagnetic wave emitting devices 530. In practical applications, the electromagnetic wave emitting devices 530 are disposed vertically in the processing chamber 510 and the wafer support 580, and thus the column of the wafer 200, is located between the electromagnetic wave emitting devices 530.

In addition, as shown in FIG. 4, the wafer support 580 is surrounded by the reflectors 520. Moreover, the electromagnetic wave emitting devices 530 are located between the reflectors 520.

With reference to the semiconductor manufacturing equipment 100 as mentioned above, the embodiments of the present disclosure further provide a method for treating the wafer 200. The method includes the following steps (it is appreciated that the sequence of the steps and the sub-steps as mentioned below, unless otherwise specified, all can be adjusted according to the actual situations, or even executed at the same time or partially at the same time):

(1) emitting a spectrum of electromagnetic wave, at least a part of the spectrum of electromagnetic wave arriving at the reflector 120.

(2) reflecting about 90.5 percent to about 99.9 percent of the said part of the spectrum of electromagnetic wave arriving at the reflector 120 to the wafer 200.

To be more specific, during the process of light treatment to the wafer 200 performed by the semiconductor manufacturing equipment 100, the electromagnetic wave emitting device 130 emits a spectrum of electromagnetic wave and at least a part of the spectrum of electromagnetic wave propagates to the wafer 200 and arrives at the wafer 200 in a period of time. In the same period of time, however, another part of the spectrum of electromagnetic wave emitted by the electromagnetic wave emitting device 130 propagates in a direction away from the wafer 200. When the spectrum of electromagnetic wave propagating away from the wafer 200 arrives at the reflector 120, the reflector 120 reflects about 90.5 percent to about 99.9 percent of the spectrum of electromagnetic wave initially propagating away from the wafer 200 back to the wafer 200. In this way, a majority of the spectrum of electromagnetic wave emitted by the electromagnetic wave emitting device 130 is directed to the wafer 200.

In order to increase the reflectance of the reflector 120, in some embodiments, the reflector 120 has a surface facing the wafer 200. The said surface of the reflector 120 includes silver. In practical applications, the silver can be coated as a layer over the reflector 120.

On the other hand, in some embodiments, in order to increase the reflectance of the reflector 120, the reflector 120 includes structurally a plurality of fibrils 121 on the said surface in a microscopic scale. The fibrils 121 are configured to reflect and refract the spectrum of electromagnetic wave such that the reflectance of the reflector 120 is increased. In other words, the fibrils 121 are present on the surface of the reflector 120 facing the electromagnetic wave emitting device 130 in a microscopic scale.

In some embodiments, the reflector 120 with the fibrils 121 may have a substantially lambertian surface facing the electromagnetic wave emitting device 130 and/or the wafer 200. In other words, the surface of the reflector 120 facing the electromagnetic wave emitting device 130 and/or the wafer 200 is substantially lambertian. A luminance of the lambertian surface of the reflector 120 facing the electromagnetic wave emitting device 130 and/or the wafer 200 is substantially isotropic, which means that a brightness of the said surface is substantially the same regardless of an observer's angle of view from about 0° to about 180°.

According to various embodiments of the present disclosure, since the reflector 120 reflects the spectrum of electromagnetic wave initially propagating away from the wafer 200 back to the wafer 200 with a reflectance ranging from about 90.5% to about 99.9%, the percentage of the spectrum of electromagnetic wave emitted by the electromagnetic wave emitting device 130 which is directed to the wafer 200 is increased by the reflector 120. As a result, for the same amount of spectrum of electromagnetic wave to be directed to the wafer 200, less power is required to generate the electromagnetic wave emitting device 130 to emit the spectrum of electromagnetic wave. Therefore, the operating cost of the semiconductor manufacturing equipment 100 is reduced, while the efficiency of the semiconductor manufacturing equipment 100 is increased.

According to various embodiments of the present disclosure, the semiconductor manufacturing equipment includes the processing chamber, at least one reflector and at least one electromagnetic wave emitting device. The reflector is present in the processing chamber. The electromagnetic wave emitting device is present between the reflector and the wafer in the processing chamber. The electromagnetic wave emitting device is configured to emit the spectrum of electromagnetic wave to the wafer. The reflector has a relative reflectance to Al₂O₃ with respect to the spectrum of electromagnetic wave, and the relative reflectance of the reflector is in a range from about 70% to about 120%.

According to various embodiments of the present disclosure, the semiconductor manufacturing equipment includes the processing chamber, the electromagnetic wave emitting device and the reflector. The electromagnetic wave emitting device is present in the processing chamber. The electromagnetic wave emitting device is configured to emit the spectrum of electromagnetic wave to the wafer. The reflector is present at the side of the electromagnetic wave emitting device opposite to the wafer, in which the reflector has the relative diffuse reflectance to Al₂O₃ with respect to the spectrum of electromagnetic wave, and the relative diffuse reflectance of the reflector is in a range from about 90% to about 110%.

According to various embodiments of the present disclosure, the method for treating the wafer includes emitting the spectrum of electromagnetic wave, at least a part of the spectrum of electromagnetic wave arriving at the reflector, and reflecting about 90.5 percent to about 99.9 percent of the said part of the spectrum of electromagnetic wave arriving at the reflector to the wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor manufacturing equipment, comprising:
a processing chamber;
at least one reflector in the processing chamber; and
at least one electromagnetic wave emitting device between the reflector and a wafer in the processing chamber, the electromagnetic wave emitting device being configured to emit a spectrum of electromagnetic wave to the wafer, wherein the reflector has a relative reflectance to Al₂O₃ with respect to the spectrum of electromagnetic wave, and the relative reflectance of the reflector is in a range from about 70% to about 120%.

2. The semiconductor manufacturing equipment of claim 1, wherein the reflector has a relative diffuse reflectance to Al₂O₃ with respect to the spectrum of electromagnetic wave, and the relative diffuse reflectance of the reflector is in a range from about 90% to about 110%.

3. The semiconductor manufacturing equipment of claim 1, wherein the reflector has a substantially lambertian surface facing the electromagnetic wave emitting device.

4. The semiconductor manufacturing equipment of claim 1, wherein the reflector is made of a material comprising silver.

5. The semiconductor manufacturing equipment of claim 1, wherein the reflector comprises:
a plurality of fibrils, the fibrils being configured to reflect and refract the spectrum of electromagnetic wave.

6. The semiconductor manufacturing equipment of claim 1, wherein the electromagnetic wave emitting device comprises at least one visible light source.

7. The semiconductor manufacturing equipment of claim 1, wherein the electromagnetic wave emitting device comprises at least one infrared source.

8. The semiconductor manufacturing equipment of claim 1, wherein the electromagnetic wave emitting device comprises at least one ultraviolet source.

9. The semiconductor manufacturing equipment of claim 1, further comprising:
a heater in the processing chamber and configured to allow the wafer to be disposed thereon.

10. The semiconductor manufacturing equipment of claim 1, further comprising:
a wafer support configured to support the wafer, wherein a plurality of the electromagnetic wave emitting devices are at opposite sides of the wafer, and the wafer support is transparent to the spectrum of electromagnetic wave.

11. The semiconductor manufacturing equipment of claim 1, further comprising:
a wafer support configured to support the wafer, wherein a plurality of the reflectors are at opposite sides of the wafer.

12. The semiconductor manufacturing equipment of claim 1, further comprising:
a wafer support configured to support the wafer, wherein the wafer support is surrounded by the electromagnetic wave emitting device.

13. The semiconductor manufacturing equipment of claim 1, further comprising:
a wafer support configured to support the wafer, wherein the wafer support is surrounded by the reflector.

14. A semiconductor manufacturing equipment, comprising:
a processing chamber;
an electromagnetic wave emitting device in the processing chamber, the electromagnetic wave emitting device being configured to emit a spectrum of electromagnetic wave to a wafer; and
a reflector at a side of the electromagnetic wave emitting device opposite to the wafer, wherein the reflector has a relative diffuse reflectance to Al₂O₃ with respect to the spectrum of electromagnetic wave, and the relative diffuse reflectance of the reflector is in a range from about 90% to about 110%.

15. The semiconductor manufacturing equipment of claim 14, wherein the reflector has a substantially lambertian surface facing the electromagnetic wave emitting device.

16. The semiconductor manufacturing equipment of claim 14, wherein the reflector has a surface facing the electromagnetic wave emitting device, and the reflector comprises a plurality of fibrils on said surface thereof.

17-20. (canceled)

21. A semiconductor manufacturing equipment, comprising:
a processing chamber;
an electromagnetic wave emitting device in the processing chamber, the electromagnetic wave emitting device being configured to emit a spectrum of electromagnetic wave to a wafer; and
a reflector at a side of the electromagnetic wave emitting device opposite to the wafer, wherein the reflector comprises a plurality of fibrils configured to reflect and refract the spectrum of electromagnetic wave.

22. The semiconductor manufacturing equipment of claim 21, wherein the fibrils are on a surface of the reflector facing the electromagnetic wave emitting device.

23. The semiconductor manufacturing equipment of claim 21, wherein the reflector has a substantially lambertian surface facing the electromagnetic wave emitting device.

24. The semiconductor manufacturing equipment of claim 21, wherein the reflector is made of a material including polytetrafluoroethene (PTFE).
